(19) United States
(12) Patent Application Publication
(10) Pub. No.: US 2011/0017282 A1
(43) Pub. Date: Jan. 27, 2011

(54) Energy transfer through coupling from photovoltaic modules

(75) Inventors: Robert Tas, Morgan Hill, CA (US); Aaron Schultz, San Jose, CA (US)

Correspondence Address: Charles H Jew, 236 West Portal Avenue, Suite 533, San Francisco, CA, 94127, US

(73) Assignee: MIASOLE

(21) Appl. No.: 12/460,847

(22) Filed: Jul. 24, 2009

(51) Int. Cl. H01L 31/00; H02J 7/35; H01F 38/14

(52) U.S. Cl. 136/252; 320/101; 307/104

(57) ABSTRACT

A photovoltaic module assembly includes a photovoltaic module which is capable of wirelessly coupling to an energy-receiving device in order to transfer energy.

### FIELD OF THE INVENTION

The present invention relates generally to a photovoltaic module assembly in which a photovoltaic module is configured to transfer energy to an energy-receiving device through wireless coupling.

### BACKGROUND OF THE INVENTION

Photovoltaic technology has received remarkable attention as a method of supplying renewable energy to devices that require energy input. Energy transfer from photovoltaic modules to energy-receiving devices is typically achieved using external wires to connect from photovoltaic modules to metal access points within energy receiving devices.

### SUMMARY OF SPECIFIC EMBODIMENTS

One embodiment of the present invention includes a photovoltaic module assembly comprising a photovoltaic module and an energy-receiving device in which the photovoltaic module is configured to transfer energy to the energy-receiving device through the use of inductive coupling.

A second embodiment of the present invention includes a photovoltaic module assembly comprising a photovoltaic module and an energy-receiving device in which the photovoltaic module is configured to transfer energy to the energy-receiving device through the use of capacitive coupling.

### BRIEF DESCRIPTION OF THE DRAWINGS

FIG. 1 is a perspective view of a photovoltaic module assembly.

FIG. 2 is a perspective, internal view of the photovoltaic module from the front face, configured for inductive coupling.

FIG. 3 is a cross-sectional view of mated E-cores.

FIG. 4 is a perspective, internal view of the photovoltaic module assembly configured for capacitive coupling.

### DETAILED DESCRIPTION OF THE PREFERRED EMBODIMENTS

Photovoltaic modules typically require the use of external wires to connect to metal access points in devices in order to transfer energy to those devices. However, many types of conditions can render such configurations disadvantageous, particularly in harsh environments. Under such conditions it might be desirable to harvest and transfer solar energy without the use of direct metal connections.

Under harsh conditions, it could be beneficial to implement a system in which a photovoltaic module can be brought in the vicinity of another device allowing energy transfer without the necessity of forming metal-to-metal wired connections between the photovoltaic module and the device. In such systems, coupling through a wireless configuration could be used to facilitate energy transfer. The resulting wireless coupling system could surmount some of the challenges that are presented by the use of metal wire connections.

The photovoltaic module and the energy-receiving device could each be separately sealed from the outside environment to facilitate efficient operation under harsh environmental conditions. Alternatively, the photovoltaic module and the energy-receiving device could be sealed together. Sealing could entail complete encapsulation allowing no externally exposed metal.

Embodiments of the present invention can be configured to apply in many situations, such as those in which a device needs to receive energy in harsh environments. For example, large ships generally operate under wet and salty conditions. In such circumstances, it could be advantageous to provide solar energy transfer without the use of direct metal connections that could increase the incidence of operational failure. To the extent that the present description describes energy transfer to an energy-receiving device, such description is not meant to limit the scope of the application of the technology.

Embodiments of the present invention can be configured to facilitate energy transfer in applications including but not limited to battery charging and primary energy source supply. Energy transfer in the present invention is intended to comprise power transfer as opposed to wireless information transfer. It is to be understood that the concepts of the present invention could just as easily be applied to facilitate other applications involving energy transfer.

Embodiments of the present invention provide a photovoltaic module and at least one energy receiving device. As used herein, the term “module” includes at least one photovoltaic cell and can include many electrically interconnected photovoltaic cells. The “energy-receiving device” is a device that is capable of receiving energy from a photovoltaic module.

FIG. 1 shows a perspective view of a photovoltaic module assembly 1 comprising a photovoltaic module 2 wirelessly coupled to an energy-receiving device 3. Energy transfer will generally occur in a direction represented by arrow 4.

Most photovoltaic modules harness solar energy and output direct current (DC). However, contactless energy transfer typically requires AC electrical excitation. Methods of energy transfer with no ohmic contact capitalize on the physics associated with permeability and/or permittivity of materials. These properties enable energy transfer at high frequency without use of direct current. As such, a photovoltaic module configured for contactless energy transfer may incorporate electronic circuitry which can perform functions such as interfacing with the electrodes of photovoltaic cells to create AC from DC.

Electronic circuitry capable of converting DC to AC is known to those skilled in the art. For example, conversion from DC to AC is employed in switching power devices, wherein high frequency capacitive coupling enables development of high side driver supplies. AC capacitive coupling is used in systems such as certain audio systems to permit only high frequency current to travel to small tweeters, as low frequency current can damage the tweeters. In another example, conversion from DC to AC is used to send energy magnetically at high frequency through a transformer whose primary is in a charging station and whose secondary is in an electric vehicle.

Electronic circuitry that converts DC to AC in the present invention could either be contained inside the large, flat portion of the photovoltaic module or could reside outside the photovoltaic module. In either circumstance, the electronic circuitry could be encapsulated with the photovoltaic module for protection from the outside environment.

Energy transfer through wireless coupling can be achieved using several different methods, including but not limited to inductive coupling and capacitive coupling. Inductively coupled systems require a means to guide magnetic field lines from one component (a primary) to a second component (a secondary). The magnetic field lines can pass through a non-magnetic material contained between two components.

Inductive coupling is particularly effective in situations where geometries of coupling interfaces allow current to flow in loops around iron cores, and wherein those iron cores can be configured so that magnetic field lines flow perpendicularly from one interface into another. In one example, photovoltaic modules might be able to develop 100 Watts of power. At such a power level, based on state of the art circuit components and techniques, inductive coupling can be employed to transfer energy from one sealed device to another. For inductively coupled systems, design elements include wire thickness, number of turns around an iron core, relative dimensions of the cross sectional area of the iron core to the distance between core pieces, iron core loss versus frequency, and turns ratios. This list is not meant to be exhaustive or limiting.

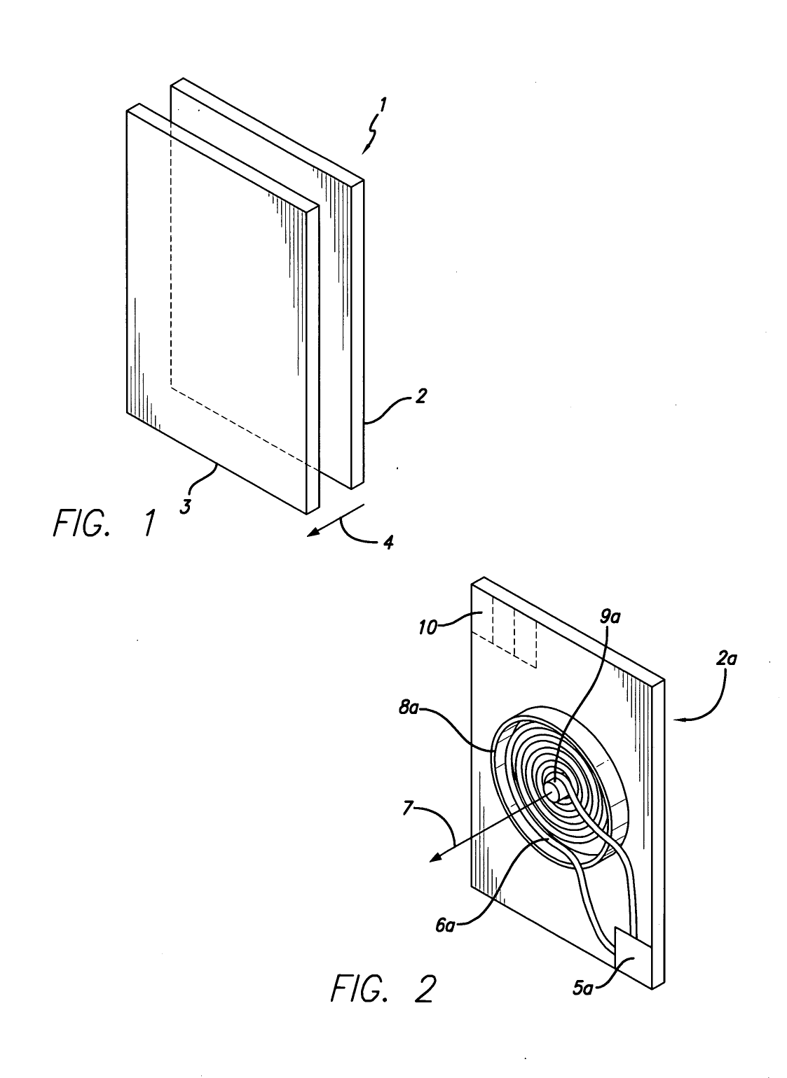

FIG. 2 shows an internal, perspective view of the front side of a photovoltaic module configured for inductive coupling. The photovoltaic module 2a comprises internal electronic circuitry 5a that performs functions such as converting DC to AC, such as an AC/DC converter. The internal electronic circuitry 5a supplies electronic current to a coiled wire configuration 6a. Circular current induces a magnetic field that extends perpendicular to the plane of the photovoltaic module 2a. The coiled wire configuration 6a can be made of any conductive material including but not limited to copper, nickel, or zirconium/copper alloy. The module could optionally contain an E-core 8a made of highly permeable metal such as iron. The E-core 8a could be placed in such a way that its middle leg 9a falls inside the coiled wire configuration 6a. The use of an E-core 8a in such a manner facilitates directing the magnetic field in a specific trajectory perpendicular to the photovoltaic module. The photovoltaic module 2 should comprise at least one photovoltaic cell 10, but may comprise multiple photovoltaic cells 10.

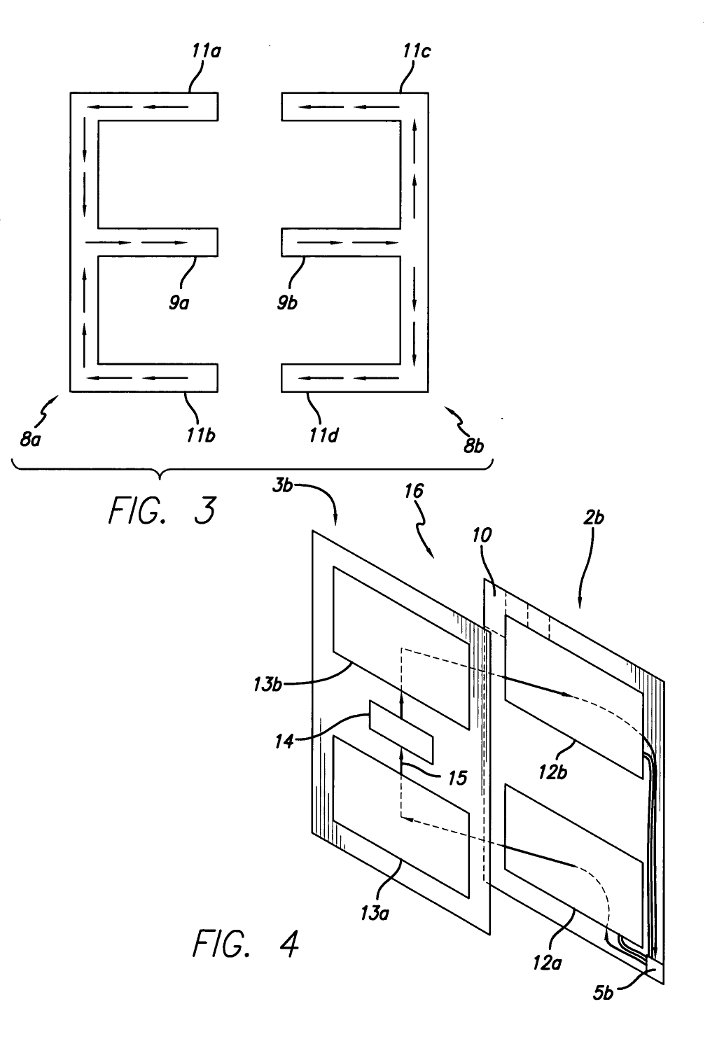

The E-core 8a contained in the photovoltaic module 2 could be mated with a second E-core, contained within an energy-receiving device 3 in order to facilitate energy transfer. FIG. 3 shows a cross-sectional view of the photovoltaic module E-core 8a mated with an E-core 8b contained in the energy-receiving device. FIG. 3 also illustrates the flow of magnetic field lines 7, which would flow through the center legs 9a, 9b of the E-cores 8a, 8b then back around to the outer legs 11a, 11b, 11c, 11d of the E-cores 8a, 8b. The effectiveness of the inductive coupling depends on the physical geometries of the system.

While the E-core 8a has been described herein as residing inside the photovoltaic module 2a, the scope of the present invention is not to be limited thereto. Other configurations could be envisioned that would not deviate from the spirit and scope of the present invention. For instance, the E-core 8a could be attached to the outside of the photovoltaic module 2a.

A substantially electrically non-conductive medium should be disposed between the photovoltaic module 2a and an energy-receiving device. For the present invention, a substantially electrically non-conductive medium should be selected such that the resistivity of the medium is between 0.01 ohm·cm and 1.0×10¹⁷ ohm·cm. Media with conductivity greater than this value may cause interference in energy transfer. Alternatively, the resistivity could be between 1.0 ohm·cm and 1.0×10¹⁵ ohm·cm. The substantially electrically non-conductive medium could comprise many different substances including but not limited to glass, non-conductive epoxy, fresh water, sea water, or air.

While certain embodiments of inductive coupling systems have been described herein, other embodiments of inductive coupling systems are within the scope of the present invention.

Capacitive coupling is an alternative method of wireless coupling that could be employed in the present invention. Capacitively coupled systems can be achieved by adjoining a large metal plate with another large metal plate in order to form a capacitor through which high frequency alternating current may flow. Applying a charge to the first plate causes the second plate to effectively act as a load by collecting the energy that is transferred thereto.

Electronic circuitry can be configured in the photovoltaic module to facilitate the conversion of DC to AC in a similar manner as described above. The AC could then couple through a capacitor of sufficiently low impedance from one side to a load to the other side. For capacitively coupled systems, the design elements include the amount of capacitance, the frequency of operation, the relative dimensions of cross sectional area to depth, and the available voltage.

FIG. 4 shows a perspective, internal view of one embodiment of the present invention in which a photovoltaic module 2b and an energy-receiving device 3b are both configured for capacitive coupling. As shown, two metal plates 12a, 12b are contained in the photovoltaic module 2b and two plates 13a, 13b are contained in the energy-receiving device 3b. Plates 12a and 13a form a first capacitor; plates 12b and 13b form a second capacitor. Electronic circuitry 5b, such as an AC/DC converter, applies an AC voltage between plate 12a and plate 12b. The series of first and second capacitor, and the energy-receiving circuitry 14 in-between, form a load for the AC source in the electronic circuitry 5b. AC current flow results from the application of voltage to this load. The resulting AC current allows for energy transfer, capacitively, through the wireless interface. Energy flow in the capacitive coupling system is illustrated by arrow 15 in FIG. 4. This current flows from the electronic circuit 5b, to plate 12a, through the interface 16, into plate 13a, through energy-receiving circuitry 14, to plate 13b, back through interface, to plate 12b, and back to the electronic circuitry 5b. The photovoltaic module 2 should comprise at least one photovoltaic cell 10, but may comprise multiple photovoltaic cells 10.

A substantially electrically non-conductive medium should be disposed between the photovoltaic module 2b and the energy-receiving device 3b. For the present invention, a substantially electrically non-conductive medium should be selected such that the resistivity of the medium is between 0.01 ohm·cm and 1.0×10¹⁷ ohm·cm. Media with conductivity greater than this value may cause interference in energy transfer. Alternatively, the resistivity could be between 1.0 ohm·cm and 1.0×10¹⁵ ohm·cm. The substantially electrically non-conductive medium could comprise many different substances including but not limited to glass, non-conductive epoxy, fresh water, sea water, or air.

Both the capacitive and inductive interfaces described herein are preferably geometrically capable of virtually ideal coupling, as imperfect coupling leads to problematic electromagnetic emissions and wasted energy. In both capacitive and inductive coupling, the area of the interface should be much larger than the distance between them. This is easily achieved in capacitive coupling if, for instance, one meter metal plates are used with a 1 mm separation between encapsulated devices. Inductive coupling depends on the nature of the coupling and the physical implementation of the photovoltaic module. It is likely sufficient if each dimension of an iron core cross section were at least 10 times the distance, such as 10 to 1,000 times the distance, that separates primary and secondary core pieces.

While the present invention has been described with reference to preferred embodiments, those skilled in the art will recognize that changes may be made in form and detail without departing from the spirit and scope of the invention.

What is claimed is:

1. A photovoltaic module assembly for transferring energy through inductive coupling from photovoltaic modules to energy-receiving devices, the photovoltaic module assembly comprising:
a photovoltaic module configured to transfer energy to an energy receiving device through wireless coupling.

2. The photovoltaic module assembly of claim 1, wherein the energy transfer occurs through non-conductive pathways.

3. The photovoltaic module assembly of claim 1, wherein the wireless coupling is inductive coupling.

4. The photovoltaic module assembly of claim 3, wherein the photovoltaic module assembly comprises an E-core inductive coupling device.

5. The photovoltaic module assembly of claim 1, wherein the wireless coupling is capacitive coupling.

6. The photovoltaic module assembly of claim 5, wherein the photovoltaic module comprises two metal plates.

7. The photovoltaic module assembly of claim 1, wherein a substantially electrically non-conductive medium is disposed between the photovoltaic module and the energy-receiving device.

8. The photovoltaic module assembly of claim 7, wherein the substantially electrically non-conductive medium is selected such that its resistivity is between 0.01 ohm·cm and 1.0×10¹⁷ ohm·cm.

9. The photovoltaic module assembly of claim 7, wherein the substantially electrically non-conductive medium is selected such that its resistivity is between 1.0 ohm·cm and 1.0×10¹⁵.

10. The photovoltaic module assembly of claim 1, wherein the photovoltaic module and the energy-receiving device are sealed together from an outside environment.

11. The photovoltaic module assembly of claim 1, wherein the photovoltaic module and the energy-receiving device are each sealed separately from the outside environment.

12. The photovoltaic module assembly of claim 1, wherein the energy is in the form of alternating current produced by conversion of direct current by electronic circuitry of the photovoltaic module.

13. The photovoltaic module assembly of claim 12, wherein the electronic circuitry comprises a DC/AC converter.

14. The photovoltaic module assembly of claim 12, wherein the electronic circuitry is contained in the photovoltaic module.

15. A method of transferring energy from photovoltaic modules to an energy-receiving device through wireless coupling, the method comprising:
transferring energy from a photovoltaic module to an energy-receiving device through wireless coupling; and
wherein the energy is transferred through a substantially electrically non-conductive medium.

16. The photovoltaic module assembly of claim 15, wherein the energy transfer occurs through non-conductive pathways.

17. The method as recited in claim 16, wherein the substantially electrically non-conductive medium is selected such that its resistivity is less than between 0.01 ohm·cm and 1.0×10¹⁷ ohm·cm.

18. The photovoltaic module assembly of claim 16, wherein the substantially electrically non-conductive medium is selected such that its resistivity is between 1.0 ohm·cm and 1.0×10¹⁵

19. The method as recited in claim 15, wherein the photovoltaic module and the energy-receiving device are sealed together from an outside environment.

20. The method as recited in claim 15, wherein the photovoltaic module and the energy-receiving device are each sealed separately from the outside environment.

21. The method as recited in claim 15, wherein the energy being transferred is in the form of alternating current that is produced by electronic circuitry of the photovoltaic module.

22. The photovoltaic module assembly of claim 21, wherein the electronic circuitry comprises a DC/AC converter.

23. The method as recited in claim 21, wherein the electronic circuitry is contained in the photovoltaic module.

24. The method as recited in claim 15, wherein the wireless coupling is inductive coupling.

25. The method as recited in claim 15, wherein the wireless coupling is capacitive coupling.

26. The method as recited in claim 15, wherein the energy-receiving device is a battery.

27. The method as recited in claim 15, wherein the energy-receiving device is a power conditioning system or LOAD.

28. A photovoltaic module assembly, comprising:
a photovoltaic module comprising at least one photovoltaic cell; and
a wireless transmission device configured to wirelessly transmit energy generated by the at least one photovoltaic cell to a receiving device.

29. The photovoltaic module assembly of claim 28, wherein the wireless transmission device comprises an inductive transmission device.

30. The photovoltaic module assembly of claim 28, wherein the wireless transmission device comprises a capacitive transmission device.

31. The photovoltaic module assembly of claim 28, further comprising a DC to AC converter electrically connected between the at least one photovoltaic cell and the wireless transmission device, wherein the converter is configured to convert DC generated by the at least one photovoltaic cell to AC and to provide AC to the wireless transmission device.

32. The photovoltaic module assembly of claim 28, further comprising the receiving device which is separated from the photovoltaic module by a gap comprising a substantially electrically non-conductive material.

33. The photovoltaic module assembly of claim 32, wherein the substantially electrically non-conductive medium is selected such that its resistivity is between 0.01 ohm·cm and 1.0×10¹⁷ ohm·cm.

34. The photovoltaic module assembly of claim 32, wherein the substantially electrically non-conductive medium is selected such that its resistivity is between 1.0 ohm·cm and 1.0×10¹⁵ ohm·cm.

35. The photovoltaic module assembly of claim 28, wherein the wireless transmission device is integrated into the photovoltaic module.

36. The photovoltaic module assembly of claim 28, wherein the wireless transmission device is located separately from the photovoltaic module.

37. A method of wirelessly transmitting energy generated by at least one photovoltaic cell to a receiving device, the method comprising:
collecting energy from a photovoltaic module comprising at least one photovoltaic cell; and
wirelessly transmitting the energy through a wireless transmission device to a receiving device.

38. The method as recited in claim 37, wherein the wireless transmission device comprises an inductive transmission device.

39. The method as recited in claim 37, wherein the wireless transmission device comprises a capacitive transmission device.

40. The method as recited in claim 37, wherein the photovoltaic module further comprises a DC to AC converter electrically connected between the at least one photovoltaic cell and the wireless transmission device, wherein the converter is configured to convert DC generated by the at least one photovoltaic cell to AC and to provide AC to the wireless transmission device.

41. The method as recited in claim 37, wherein the photovoltaic module is separated from the receiving device by a gap comprising a substantially electrically non-conductive material.

42. The method as recited in claim 41, wherein the substantially electrically non-conductive medium is selected such that its resistivity is between 0.010 ohm·cm and 1.0×10¹⁷ ohm·cm.

43. The method as recited in claim 41, wherein the substantially electrically non-conductive medium is selected such that its resistivity is between 1.0 ohm·cm and 1.0×10¹⁵ ohm·cm.

44. The method as recited in claim 37, wherein the wireless transmission device is integrated into the photovoltaic module.

45. The method as recited in claim 37, wherein the wireless transmission device is located separately from the photovoltaic module.
